(19) United States
(12) Patent Application Publication
(10) Pub. No.: US 2011/0266530 A1
(43) Pub. Date: Nov. 3, 2011

(54) ORGANIC LIGHT EMITTING DEVICE

(76) Inventors: Soo-Jin Park, Yongin-city (KR); Keon-Ha Choi, Yongin-city (KR); Dae-Yup Shin, Yongin-city (KR); Seung-Gak Yang, Yongin-city (KR)

(21) Appl. No.: 13/094,763

(22) Filed: Apr. 26, 2011

(30) Foreign Application Priority Data
Apr. 28, 2010 (KR) 10-2010-0039494

(51) Int. Cl. H01L 51/54

(52) U.S. Cl. 257/40; 257/E51.018

(57) ABSTRACT

An organic light emitting device having improved hole injection and hole transport capabilities is disclosed, wherein the device includes a first electrode, an organic layer, and a second electrode, wherein the organic layer includes a compound represented by Formula 1 and a phenylamine-based compound. Formula 1 together with the phenylamine-based compound improves the charge mobility of the hole transport layer.

### CROSS-REFERENCE TO RELATED APPLICATION

This application claims priority to and the benefit of Korean Patent Application No. 10-2010-0039494, filed on Apr. 28, 2010, in the Korean Intellectual Property Office, the entire content of which is incorporated herein by reference.

### BACKGROUND

1. Field

The following description relates to an organic light emitting device, and more particularly, to an organic light emitting device having improved hole injection and hole transport capabilities.

2. Description of Related Art

Organic light emitting devices are charge injection type emitting devices and self-emission type display devices, wherein light is emitted by a recombination of electrons injected from an anode and holes injected from a cathode in an emission layer or at an interface between an emission layer and a hole or electron (carrier) transport layer.

In order to improve the luminescence efficiency of the organic light emitting device, electrons and holes injected into an emission layer need to be well balanced.

Emitting sites move according to the number of electrons and holes injected into an emission layer. For example, when the number of holes is greater than that of electrons, the emission sites move from an emission layer to a region adjacent to an electron transport layer. When the number of electrons is greater than that of holes, the emission sites move from an emission layer to a region adjacent to a hole transport layer. Accordingly, when the emission sites are moved, the efficiency and lifetime characteristics of the organic light emitting devices may vary.

In order to adjust a charge balance of electrons and holes injected into an emission layer, materials for forming a hole transport layer and an electron transport layer may be changed. Use of tetracyanoquinodimethane (TCNQ) has been suggested for forming a hole transport layer doped with a P-dopant. However, the molecular weight of the TCNQ material is too small, resulting in a material that has poor deposition characteristics compared to a material that is deposited at a lower temperature than a deposition temperature required to manufacture a conventional organic light emitting device. Accordingly, there is a need for an alternative to p-doping.

### SUMMARY

An aspect of an embodiment of the present invention is directed toward, an organic light emitting device having improved driving voltage by forming a charge transport layer using a material having increased charge mobility.

According to an embodiment of the present invention, there is provided an organic light-emitting device including: a first electrode, an organic layer, and a second electrode, wherein the organic layer includes a compound of Formula 1 and a phenylamine-based compound

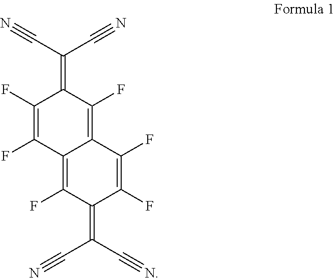

In one embodiment, the amount of the compound of Formula 1 is in a range of about 1 to about 10 parts by weight based on 100 parts by weight of the total weight of the compound of Formula 1 and the phenylamine compound.

In one embodiment, the phenylamine-based compound includes a compound selected from the group consisting of N,N′-Di-[(1-naphthalenyl)-N—N′-diphenyl]-1,1′-biphenyl)-4,4′-diamine (NPB), N,N′-di-(3-methylphenyl)-N,N-diphenyl-4,4′-diaminobiphenyl (TPD), and mixtures thereof.

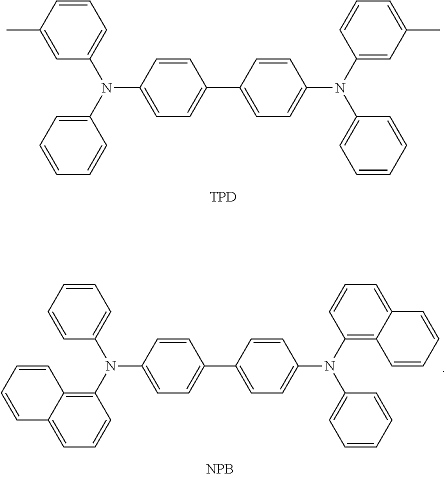

In one embodiment, the organic layer is a hole injection layer, a hole transport layer, or an intermediate layer functioning as a hole injection layer and a hole transport layer.

In one embodiment, the organic light-emitting device further includes is a hole injection layer, an emission layer, an electron transport layer, and/or an electron injection layer.

In one embodiment, the hole injection layer includes a material selected from copper phthalocyanine (CuPc), 4,4′,4″-tris(3-methylphenylphenylamino) triphenylamine (m-MTDATA), N,N′-di(1-naphthyl)-N,N′-diphenylbenzidine (NPB), (4,4′,4″-tris(N,N-diphenylamino)triphenylamine) (TDATA), (4,4,4-tris(n-(2-naphthyl)-n-phenyl-amino)-triphenylamine) (2-TNATA), (Polyaniline/Dodecylbenzenesulfonic acid) (Pani/DBSA), (Poly(3,4-ethylenedioxythiophene)/Poly(4-styrenesulfonate) (PEDOT/PSS), Pani/CSA (Polyaniline/Camphor sulfonicacid), (Polyaniline)/Poly-(4-styrenesulfonate) (PANI/PSS), or combinations thereof.

In one embodiment, the organic light-emitting device further includes an emission layer including a phosphorescent dopant.

In one embodiment, the phosphorescent dopant is Ir(2-phenylpyridine)₃ (Ir(ppy)₃), iridiumbis[4,6-di-fluorophenyl)-pyridinato-N,C2′]picolinate (F₂Irpic). or mixtures thereof.

### BRIEF DESCRIPTION OF THE DRAWINGS

The accompanying drawings, together with the specification, illustrate exemplary embodiments of the present invention, and, together with the description, serve to explain the principles of the present invention.

FIG. 1 is a graph showing voltage-current density characteristics of organic light emitting devices of Example 1 and Comparative Example 1;

FIG. 2 is a graph showing logs of current density expressed numerically from among the voltage-current density characteristics of organic light emitting devices of Example 1 and Comparative Example 1;

FIG. 3 is a graph showing a result of differential scanning calorimeter (DSC) of compound of Formula 1; and

FIG. 4 is a graph showing a result of F¹⁹ nuclear magnetic resonance (NMR) spectrometry for compound of Formula 1.

### DETAILED DESCRIPTION

An organic light emitting device according to an embodiment of the present invention includes a first electrode, an organic layer, and a second electrode.

The organic layer includes a compound represented by Formula 1 below and a phenylamine-based compound.

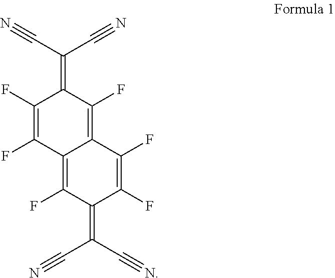

The compound represented by Formula 1 is characteristically similar to a p-dopant material, and has an energy at a lowest unoccupied molecular orbital (LUMO) level that is similar to the energy at a highest occupied molecular orbital (HOMO) level corresponding to a forming material of a hole transport layer. Also, a compound represented by Formula 1 has excellent thermal characteristic and a deposition temperature in a range of 150 to 250° C. (or, about 150 to about 250° C.) so that manufacturing of the organic layer is relatively easy.

Examples of the phenylamine-based compound include N,N′-Di-[(1-naphthalenyl)-N—N′-diphenyl]-1,1′-biphenyl)-4,4′-diamine (NPB) represented by the below formula, N,N′-di-(3-methylphenyl)-N,N-diphenyl-4,4′-diaminobiphenyl (TPD) represented by the below formula, and mixtures thereof

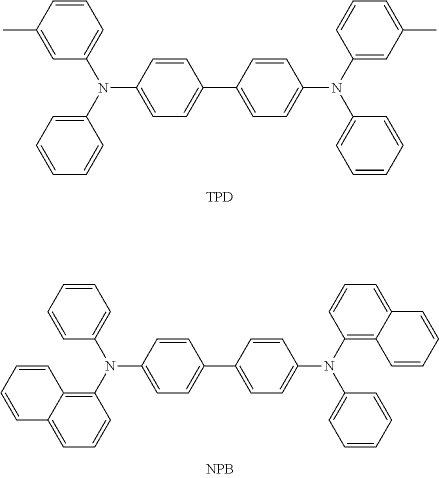

In one embodiment the amount of the compound of Formula 1 in the organic layer is in a range of 1 to 10 parts (or, about 1 to about 10 parts) by weight based on 100 parts by weight of the total weight of the compound of Formula 1 and the phenylamine-based compound.

In one embodiment, when the amount of the compound of Formula 1 is within the above range, the organic light emitting device has excellent performance, for example, in terms of luminescence efficiency. The compound of Formula 1 may be homogeneously or ununiformly dispersed in the organic layer.

In one embodiment the organic layer is a hole injection layer, a hole transport layer, or an intermediate layer functioning as a hole injection layer and a hole transport layer.

In one embodiment, the organic light emitting device also includes at least one selected from the group consisting of a hole injection layer, an emission layer, an electron transport layer, and/or an electron injection layer.

When the organic light emitting device includes an electron transport layer, the electron transport layer can be formed of any suitable material for forming an electron transport layer, for example, (8-hydroxyquinoline)aluminum (Alq3).

Alternatively, the ETL may include an electron transporting organic compound and a metal-containing material. Examples of the electron transporting organic compound unlimitedly include AND (9,10-di(naphthalene-2-il)anthracene); and anthracene-based compounds represented by Compounds 101 or 102 below, but are not limited thereto.

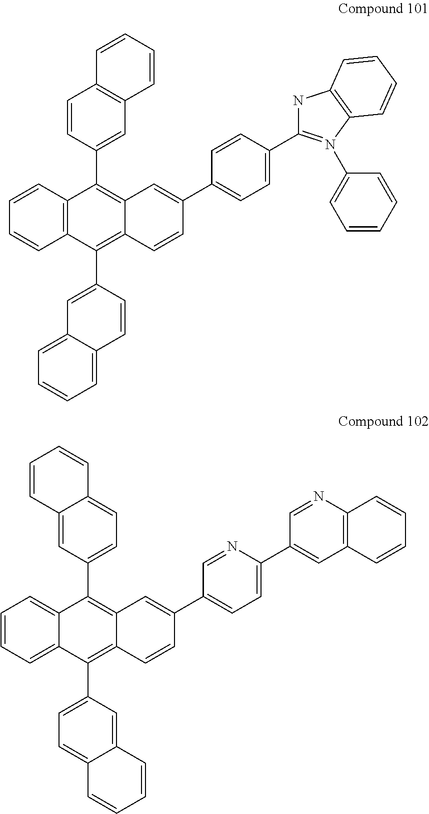

The metal-containing material may include an Li complex. Examples of the Li complex unlimitedly include lithium quinolate (LiQ) or Compound 103 below.

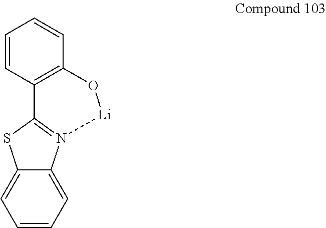

In one embodiment, the organic light emitting device has a structure in which a first electrode, a hole injection layer, a hole transport layer, an emission layer, and a second electrode are sequentially stacked; a structure in which a first electrode, a hole transport layer, an emission layer, a hole transport layer, and a second electrode are sequentially stacked; or a structure in which a first electrode, a hole injection layer, a hole transport layer, an emission layer, an electron transport layer, a second electrode are sequentially stacked. In an alternative embodiment, the organic light emitting device has an inverted type structure in which a first electrode, an electron injection layer, a hole transport layer, an emission layer, a hole transport layer, a hole injection layer, and a second electrode are sequentially stacked.

A method of manufacturing the organic light emitting device according to one or more embodiments of the present invention, is as follows.

Firstly, a first electrode is formed on a substrate. The substrate, which may be any substrate used in organic light-emitting devices, may be a glass substrate or a transparent plastic substrate with excellent transparency, surface smoothness, ease of handling, and/or water resistance. In one embodiment, the thickness of the substrate is in a range of 0.3 to 1.1 mm (or, about 0.3 to about 1.1 mm).

The first electrode may be formed of a transparent and highly conductive material, such as indium tin oxide (ITO), indium zinc oxide (IZO), tin oxide (SnO₂), zinc oxide (ZnO), or a mixture thereof.

A hole injection layer is selectively formed on the first electrode of a hole injection material.

The hole injection material may be the compound represented by Formula 1, the phenylamine-based compound, and/or a well known hole injection material.

Examples of the hole injection material may include, but are not limited to, a phthalocyanine compound such as copper phthalocyanine (CuPc), m-MTDATA [4,4′,4″-tris(3-methylphenylphenylamino)triphenylamine], NPB(N,N′-di(1-naphthyl)-N,N′-diphenylbenzidine), TDATA (4,4′,4″-tris(N,N-diphenylamino)triphenylamine), 2-TNATA (4,4,4-tris(n-(2-naphthyl)-n-phenyl-amino)-triphenylamine), Pani/DBSA (Polyaniline/Dodecylbenzenesulfonic acid), PEDOT/PSS(Poly(3,4-ethylenedioxythiophene)/Poly(4-styrenesulfonate)), Pani/CSA (Polyaniline/Camphor sulfonicacid), PANI/PSS (Polyaniline)/Poly(4-styrenesulfonate)), and combinations thereof.

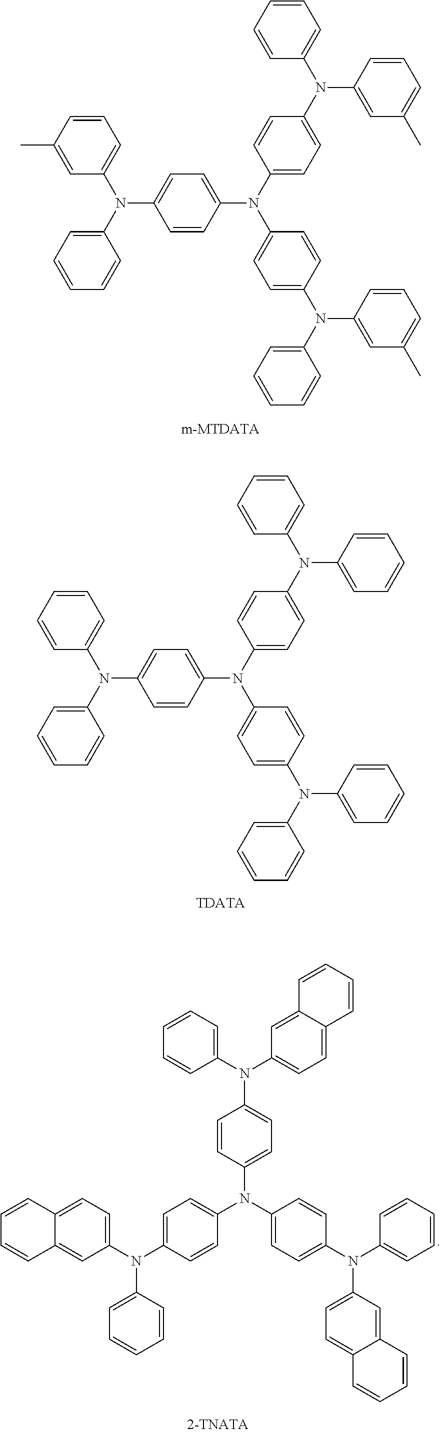

In one embodiment a compound of Formula 1, is the hole transport material, and is deposited together with a phenylamine-based compound, onto the hole injection layer, thereby forming a hole transport layer.

Examples of the phenylamine-based material used to form the hole transport layer include, but are not limited to, NPB and TPD.

An emission layer is formed on the hole transport layer. The emission layer may be formed by using vacuum deposition, spin coating, casting, Langmuir-Blodgett (LB) deposition, and/or the like.

The emission layer includes a phosphorescent dopant. As the phosphorescent dopant is used, highly efficient emitting devices can be manufactured.

The phosphorescent dopant may be an organic metal complex including Ir, Pt, Os, Re, Ti, Zr, Hf, or a combination of at least two thereof, but is not limited thereto.

Examples of the phosphorescent dopant include Ir(PPy)₃(PPy=2-phenylpyridine) and F₂Irpic {iridiumbis[4,6-di-fluorophenyl)-pyridinato-N,C2′]picolinate}.

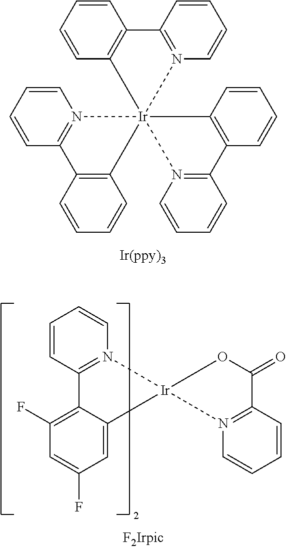

In one embodiment, the amount of the phosphorescent dopant in the emission layer is in a range of 0.1 to 15 parts (or, about 0.01 to about 15 parts) by weight based on 100 parts by weight of a total amount of a host and a dopant.

When the emission layer includes a phosphorescent dopant, a hole blocking layer (HBL) can be further formed on the emission layer by using vacuum deposition and/or spin coating to prevent or protect from diffusion of triplet excitons and/or holes into the emission layer. The HBL may be formed of any suitable material. Examples of known HBL-forming materials include an oxadiazole derivative, a triazole derivative, a phenanthroline derivative, BCP (2,9-Dimethyl-4,7-diphenyl-1,10-phenanthroline), and mixtures thereof.

Alq₃ (tris(8-hydroxy)quinoline aluminium) or CBP (4,4′-N,N′-dicarbazole-biphenyl) is used as the host of the emission layer.

The emission layer according to an embodiment of the present invention includes 85 parts by weight of CBP and 15 parts by weight of Ir(PPy)₃.

An electron transport layer is formed on the emission layer by using an electron transport material. In the present invention, the electron transport layer is formed by using vacuum deposition.

The electron transport layer may have a thickness of 150 Å to 600 Å (or, about 150 Å to about 600 Å). When the thickness of the electron transport layer is within the above range, a driving voltage is improved without decreasing the electron transport capability.

An electron injection layer is formed on the hole transport layer by using an electron injection material.

The electron injection layer may be formed of LiF, NaCl, CsF, Li₂O, BaO, and/or the like. Deposition or coating conditions for forming the electron transport layer and the electron injection layer are similar to those for the formation of the hole injection layer, although the deposition or coating conditions may vary according to materials that are used to form the electron transport layer and the electron injection layer.

A thickness of the electron injection layer is in a range of 1 to 300 Å (or, about 1 to about 300 Å), or for example, 5 to 90 Å (or, about 5 to about 90 Å).

A cathode-forming metal is deposited on the electron injection layer by using vacuum deposition or sputtering, thereby forming a cathode, which is a second electrode. Examples of the cathode-forming metal may include, but are not limited to, lithium (Li), magnesium (Mg), aluminum (Al), aluminum-lithium (Al—Li), calcium (Ca), magnesium-indium (Mg—In), and magnesium-silver (Mg—Ag). In addition, a transparent cathode formed of ITO or IZO may be used to produce a top-emission light-emitting device.

An embodiment of the inventive concept will now be described in greater detail with reference to the following examples. These examples are for illustrative purposes only and are not intended to limit the scope of the inventive concept.

### SYNTHESIS EXAMPLE 1

### Preparation of Compound Represented by Formula 1

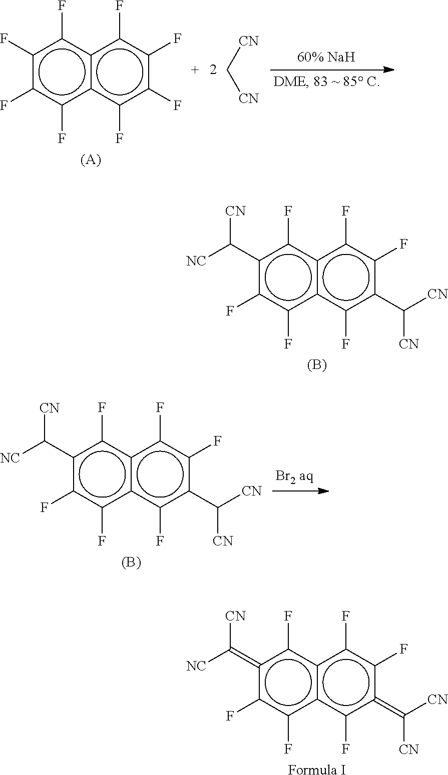

11.8 g of NaH (60 wt % dispersion in mineral oil) was dissolved in dimethoxy ethane (DME) to prepare a mixture solution. 10.7 g of malononitrile was added to the mixture solution and then 20.0 g of compound (A) was added thereto to prepare a reaction solution. The reaction solution was reacted for 24 hours while refluxing it and then was concentrated at a reduced pressure, thereby removing a solvent. Accordingly, 5.7 g of a light-grey color compound B as a remaining material was obtained with a yield of 21.0%.

10.0 g of compound B was dissolved in 4 wt % heavy water and then 7.5 g of sodium acetate and 5 ml of an acetic acid were added thereto to prepare a mixture solution. Then, 2.5 wt % of an aqueous Br₂ solution was added to the mixture solution until a KI test paper was positive. The resulting green solid precipitate was filtered to obtain 2.5 g of the compound of Formula 1 with a yield of 25.1%.

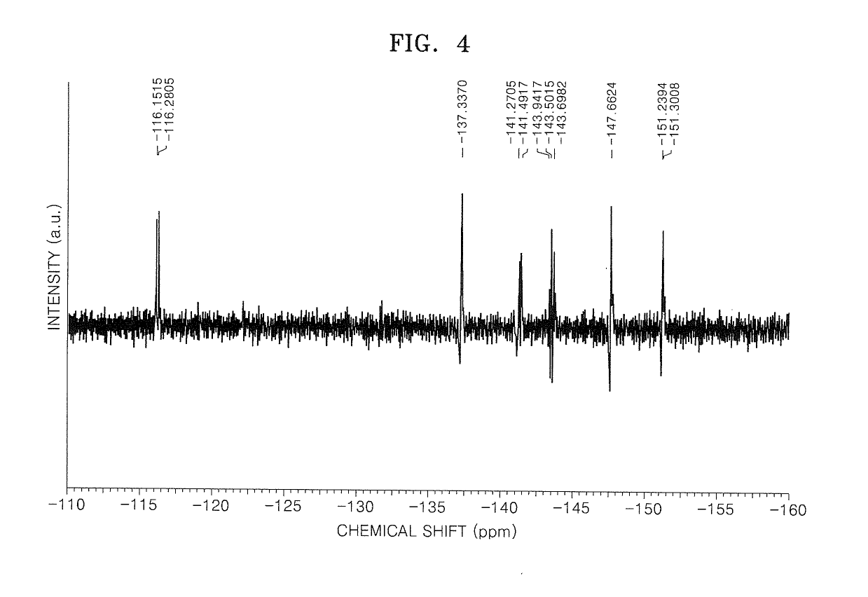

The structure of the compound of Formula 1 was identified using F¹⁹ nuclear magnetic resonance (NMR) spectrometry (see FIG. 4).

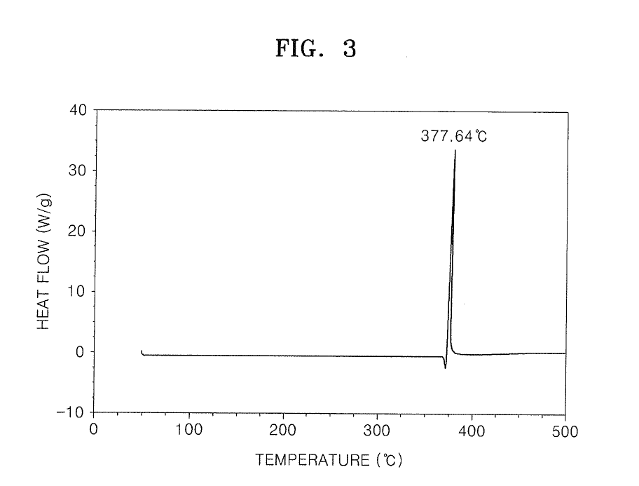

The compound of Formula 1 was analyzed using a differential scanning calorimeter (DSC). The results are shown in FIG. 3.

### EXAMPLE 1

An anode was manufactured from a 10 Ω/cm² ITO substrate (available from Corning Co.). 98 parts by weight of the compound of Formula 1 and 2 parts by weight of NPB were co-deposited on the substrate in a vacuum to form a hole transport layer having a thickness of about 600 Å.

An Al metal was deposited on the hole transport layer so as to form an electrode and thus an organic light emitting device was manufactured.

### COMPARATIVE EXAMPLE 1

An organic light emitting device was manufactured in the same manner as in Example 1, except that only NPB was used instead of the compound of Formula 1 and NPB to form the hole transport layer.

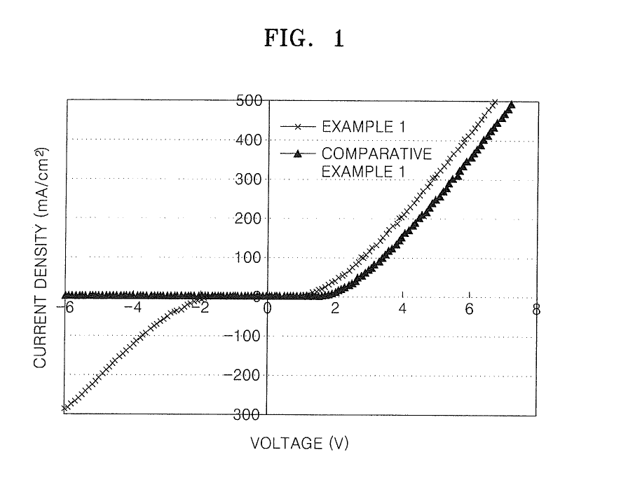

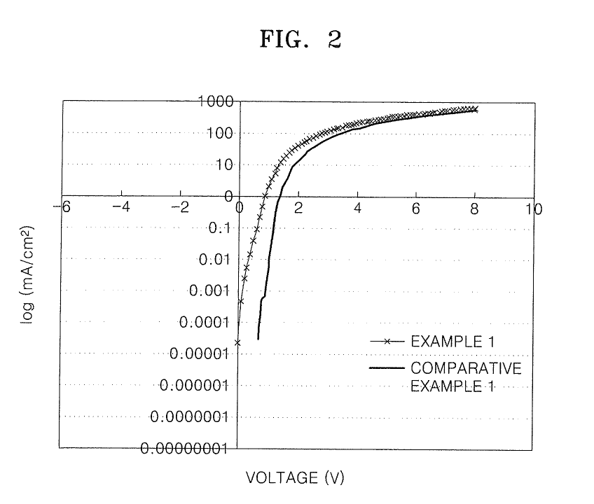

Voltage characteristics according to current density were measured in the organic light emitting devices of Example 1 and Comparative Example 1 and the results are shown in FIGS. 1 and 2.

Referring to FIGS. 1 and 2, the organic light-emitting device of Example 1 has improved voltage characteristics, as compared to the organic light-emitting device of Comparative Example 1.

FIG. 1 shows curved lines of current density versus voltages of the organic light emitting devices and the current density in FIG. 2 is expressed numerically. In the organic light emitting device of Example 1, a hole charge density is theoretically increased and a current flows at a low voltage so that performance of the organic light emitting device with a low voltage is improved.

In view of the foregoing, an organic light emitting device according to an embodiment of the present invention has improved hole injection, hole transport, and electron transport capabilities, thereby improving the driving voltage.

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

1. An organic light-emitting device comprising:
a first electrode;
an organic layer; and
a second electrode,
wherein the organic layer comprises a compound of Formula 1 and a phenylamine-based compound

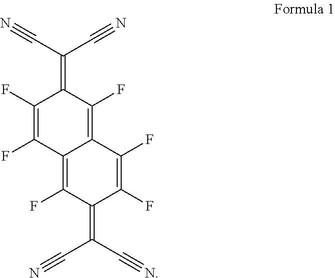

2. The organic light-emitting device of claim 1, wherein the amount of the compound of Formula 1 is in a range of about 1 to about 10 parts by weight based on 100 parts by weight of the total weight of the compound of Formula 1 and the phenylamine-based compound.

3. The organic light-emitting device of claim 1, wherein the phenylamine-based compound comprises a compound from the group consisting of N,N′-Di-[(1-naphthalenyl)-N—N′-diphenyl]-1,1′-biphenyl)-4,4′-diamine (NPB) having the below formula and N,N′-di-(3-methylphenyl)-N,N-diphenyl-4,4′-diaminobiphenyl (TPD), having the below formula, and mixtures thereof,

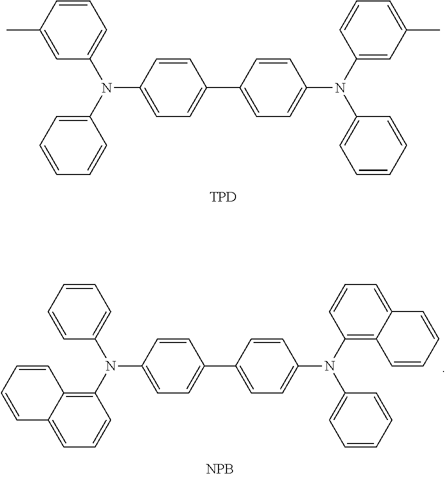

4. The organic light-emitting device of claim 1, wherein the organic layer is a hole injection layer, a hole transport layer, or an intermediate layer functioning as a hole injection layer and a hole transport layer.

5. The organic light-emitting device of claim 1, further comprising at least one selected from the group consisting of a hole injection layer, an emission layer, an electron transport layer, and an electron injection layer.

6. The organic light-emitting device of claim 5, wherein the hole injection layer comprises a material selected from the group consisting of copper phthalocyanine (CuPc), 4,4′,4″-tris(3-methylphenylphenylamino) triphenylamine (m-MTDATA), N,N′-di(1-naphthyl)-N,N′-diphenylbenzidine (NPB), (4,4′,4″-tris(N,N-diphenylamino)triphenylamine) (TDATA), (4,4,4-tris(n-(2-naphthyl)-n-phenyl-amino)-triphenylamine) (2-TNATA), (Polyaniline/Dodecylbenzenesulfonic acid) (Pani/DBSA), (Poly(3,4-ethylenedioxythiophene)/Poly(4-styrenesulfonate) (PEDOT/PSS), Pani/CSA (Polyaniline/Camphor sulfonicacid), (Polyaniline)/Poly-(4-styrenesulfonate) (PANI/PSS), and combinations thereof.

7. The organic light-emitting device of claim 1, further comprising an emission layer including a phosphorescent dopant.

8. The organic light-emitting device of claim 7, wherein the phosphorescent dopant is Ir(2-phenylpyridine)3 (Ir(ppy)3), iridiumbis[4,6-di-fluorophenyl)-pyridinato-N,C2′]picolinate (F2Irpic), and/or mixtures thereof.

9. The organic light-emitting device of claim 7, wherein the phosphorescent dopant is an organic metal complex including Ir, Pt, Os, Re, Ti, Zr, Hf, or a combination of at least two thereof.

10. The organic light-emitting device of claim 5, wherein the electron transport layer comprises an electron transporting organic compound and a metal-containing material.

11. The organic light-emitting device of claim 10, wherein the metal-containing material comprises an Li complex.
